(19) United States
(12) Patent Application Publication
(10) Pub. No.: US 2025/0248219 A1
(43) Pub. Date: Jul. 31, 2025

(54) DISPLAY PANEL AND MANUFACTURING METHOD THEREFOR, AND DISPLAY DEVICE

(71) Applicants: Hefei Visionox Technology Co., Ltd., Hefei (CN); Visionox Technology Inc., Suzhou (CN)

(72) Inventors: Zhiwei ZHOU, Hefei (CN); Jinfang ZHANG, Hefei (CN); Lu ZHANG, Hefei (CN); Yulong MA, Hefei (CN)

(73) Assignees: Hefei Visionox Technology Co., Ltd., Hefei (CN); Visionox Technology Inc., Suzhou (CN)

(21) Appl. No.: 18/749,639

(22) Filed: Jun. 21, 2024

(30) Foreign Application Priority Data
Jan. 29, 2024 (CN) 202410125513.9

(51) Int. Cl. H10K 59/122; H10K 59/12; H10K 59/80

(52) U.S. Cl. CPC H10K 59/122; H10K 59/1201; H10K 59/8792

(57) ABSTRACT

Disclosed are a display panel and a manufacturing method therefor, and a display device. The display panel includes a substrate, and a display functional layer, an isolation structure, a pixel defining layer, and a shielding layer located on the substrate. The isolation structure is located on the substrate, and defines a plurality of light-transmitting openings and a plurality of isolation openings. The pixel defining layer is located between the isolation structure and the substrate, and includes a plurality of pixel openings. The shielding layer includes a plurality of first shielding units located between the pixel defining layer and the substrate. The first shielding unit corresponds to at least part of the light-transmitting openings, and at least partially overlaps with the corresponding light-transmitting opening. Thus, shielding at the light-transmitting opening may be provided by the shielding layer to avoid signal interference while ensuring the light transmittance of the light-transmitting opening.

### CROSS-REFERENCE TO RELATED APPLICATIONS

This application claims priority to Chinese Patent Application No. 202410125513.9, filed on Jan. 29, 2024, which is hereby incorporated by reference in its entirety.

### TECHNICAL FIELD

Embodiments of the present disclosure relate to the field of display technologies, and in particular, to a display panel and a manufacturing method therefor, and a display device.

### BACKGROUND

An Organic Light-Emitting Diode (OLED) is a kind of organic thin-film electroluminescent device. Due to its advantages such as simple preparation process, low cost, low power consumption, high brightness, wide viewing angle, high contrast, and an ability to achieve flexible display, it has attracted great attention and has been widely used in electronic display products.

However, currently, electronic display products are limited by design of their own structures, making it difficult to achieve good display functions when applied in scenarios such as under-screen recognition and transparent display.

### SUMMARY

A first aspect of the present disclosure provides a display panel. The display panel includes a substrate, and a display functional layer, an isolation structure, a pixel defining layer, and a shielding layer located on the substrate. The display functional layer includes a plurality of light-emitting devices located on the substrate. The isolation structure is located on the substrate, and defines a plurality of light-transmitting openings and a plurality of isolation openings. The pixel defining layer is located between the isolation structure and the substrate, and includes a plurality of pixel openings in one-to-one correspondence with the plurality of isolation openings. The isolation opening and the pixel opening are configured to confine the light-emitting device. The shielding layer includes a plurality of first shielding units located between the pixel defining layer and the substrate, and the first shielding unit corresponds to at least part of the light-transmitting openings. An orthographic projection of the first shielding unit on the substrate at least partially overlaps with an orthographic projection of the corresponding light-transmitting opening on the substrate. A through hole is provided in the pixel defining layer, and the first shielding unit is connected to the isolation structure through the through hole.

In the technical solution mentioned above, shielding at the light-transmitting opening may be provided by the shielding layer to avoid signal interference while ensuring the light transmittance of the light-transmitting opening.

A second aspect of the present disclosure provides a display panel, and the display panel includes a substrate, a display functional layer and a shielding layer. The display functional layer includes a plurality of light-emitting devices located on the substrate, and the light-emitting device includes a first electrode, a light-emitting functional layer, and a second electrode sequentially stacked on the substrate. An isolation structure located on the substrate, and defines a plurality of light-transmitting openings and a plurality of isolation openings. The isolation opening is configured to confine the light-emitting device, and the light-emitting functional layer and the second electrode are located in the corresponding isolation opening. The shielding layer includes a plurality of first shielding units. The first shielding unit corresponds to at least part of the light-transmitting openings, and an orthographic projection of the first shielding unit on the substrate at least partially overlaps with an orthographic projection of the corresponding light-transmitting opening on the substrate. The first shielding unit is connected to the isolation structure. At least part of the first electrode is located on a same layer as the first shielding unit and is composed of a same material as the first shielding unit.

A third aspect of the present disclosure provides a display device, and the display device may include a display panel according to any specific implementation of the first aspect and the second aspect mentioned above.

A fourth aspect of the present disclosure provides a manufacturing method for a display panel. The manufacturing method includes: providing a substrate and forming a pixel defining layer, an isolation structure, a plurality of first shielding units, and a plurality of first electrodes on the substrate, where a plurality of light-transmitting openings and a plurality of isolation openings respectively corresponding to the first electrode are formed in the isolation structure, the pixel defining layer is formed between the isolation structure and the substrate and a plurality of pixel openings in one-to-one correspondence with the plurality of isolation openings are formed in the pixel defining layer, the first shielding unit is formed between the pixel defining layer and the substrate and corresponds to at least part of the light-transmitting openings, an orthographic projection of the first shielding unit on the substrate at least partially overlaps with an orthographic projection of the corresponding light-transmitting opening on the substrate, a through hole is formed in the pixel defining layer, and the first shielding unit is connected to the isolation structure through the through hole; sequentially depositing a light-emitting functional material layer and a conductive material layer, where the light-emitting functional material layer and the conductive material layer cover the isolation structure, the isolation opening, and the light-transmitting opening; forming a first encapsulation material layer on a side, away from the substrate, of the conductive material layer; performing patterning process on the light-emitting functional material layer, the conductive material layer, and the first encapsulation material layer to remove the light-emitting functional material layer, the conductive material layer, and the first encapsulation material layer corresponding to at least part of the light-transmitting openings and at least part of the isolation openings, where a light-emitting functional layer is formed by the remaining light-emitting functional material layer, a second electrode is formed by the remaining conductive material layer, an encapsulation unit is formed by the remaining first encapsulation material layer, and a light-emitting device is formed by the light-emitting functional layer, the second electrode, and the first electrode corresponding to the isolation opening where the light-emitting functional layer and the second electrode are located; and repeating the process of preparing the light-emitting functional layer, the second electrode, and the encapsulation unit at the isolation opening where the light-emitting functional layer has not been formed, until the light-emitting device and the encapsulation unit are formed in each of the plurality of isolation openings, where a display functional layer is formed by the light-emitting device, and a first encapsulation layer is formed by the encapsulation unit.

### BRIEF DESCRIPTION OF THE DRAWINGS

FIG. 1 is a schematic planar structural diagram of a display panel according to an embodiment of the present disclosure, showing a display substrate of the display panel.

FIG. 2 is an enlarged view of an area of S1 in a design of the display panel shown in FIG. 1.

FIG. 3 is a sectional view along M1-N1 in a design of the display panel as shown in FIG. 2.

FIG. 4 is a sectional view along M2-N2 of the display panel as shown in FIG. 2.

FIG. 5A is a schematic planar structural diagram of a touch electrode of a display panel according an embodiment of the present disclosure, where an area of S2 in FIG. 5A corresponds to the area of S1 in FIG. 1.

FIG. 5B is a sectional view along M3-N3 of the touch electrode as shown in FIG. 5A.

FIG. 6A is a schematic planar structural diagram of a touch electrode of a display panel according an embodiment of the present disclosure, where an area of S3 in FIG. 6A corresponds to the area of S1 in FIG. 1.

FIG. 6B is a sectional view along M4-N4 of the touch electrode as shown in FIG. 6A.

FIG. 7A is an enlarged view of the area of S1 in another design of the display panel shown in FIG. 1, illustrating a different pixel layout compared to FIG. 2.

FIG. 7B is a schematic planar structural diagram of the touch structure shown in FIG. 7A.

FIG. 8A is an enlarged view of the area of S1 in still another design of the display panel shown in FIG. 1, illustrating a different pixel layout relative to FIG. 2.

FIG. 8B is a schematic planar structural diagram of the touch structure shown in FIG. 8A, which is different from the touch structures shown in FIGS. 7A and 7B.

FIG. 9 is a sectional view along M1-N1 in another design of the display panel shown in FIG. 2.

FIG. 10 is a schematic diagram of a positional relationship of some structures in a display panel according to an embodiment of the present disclosure

FIG. 11A is a sectional view along M5-N5 in a design of the display panel as shown in FIG. 10.

FIG. 11B is a sectional view along M5-N5 in another design of the display panel as shown in FIG. 10.

FIG. 12 is a sectional view along M5-N5 in still another design of the display panel as shown in FIG. 2.

FIG. 13 is a sectional view along M5-N5 in yet still another design of the display panel as shown in FIG. 2.

FIG. 14 is a flowchart of a manufacturing method for a display panel according to an embodiment of the present disclosure.

FIGS. 15A to 15G are process diagrams of a manufacturing method for a display panel according to an embodiment of the present disclosure.

FIG. 16 is a flowchart of another manufacturing method for a display module according to an embodiment of the present disclosure.

FIG. 17 is a flowchart of still another manufacturing method for a display module according to an embodiment of the present disclosure.

### DETAILED DESCRIPTION OF THE EMBODIMENTS

A clear and comprehensive description of the technical solutions in embodiments of the present specification will be provided with reference to accompanying drawings in the embodiments of the present specification in the following. It is evident that the described embodiments are merely a part of the embodiments in this specification, rather than all of them. All other embodiments obtained by those skilled in the art without making any creative effort based on the embodiments in this specification fall within the protection scope of this specification.

In some display products, some functional film layers in a light-emitting device are formed through evaporation. As there are various functional film layers in each light-emitting device, and some functional film layers (such as the light-emitting layer) of the light-emitting devices emitting different lights are made of different materials, aligning processes are needed for many times when evaporating these functional film layers through mask plates (such as fine mask plates). To address an issue of positional offset caused by alignment accuracy errors, sufficient space (i.e., a safety margin related to the alignment error) needs to be reserved between different light-emitting devices to ensure that the actual light-emitting area of the light-emitting devices overlaps with the design position (design area) in a certain degree. However, this effectively reduces the design area of the light-emitting area of the light-emitting devices, not only limiting the light-emitting area but also preventing a further increase in the arrangement density of the light-emitting devices. Consequently, it becomes difficult to further increase PPI (pixels per inch) of a display panel.

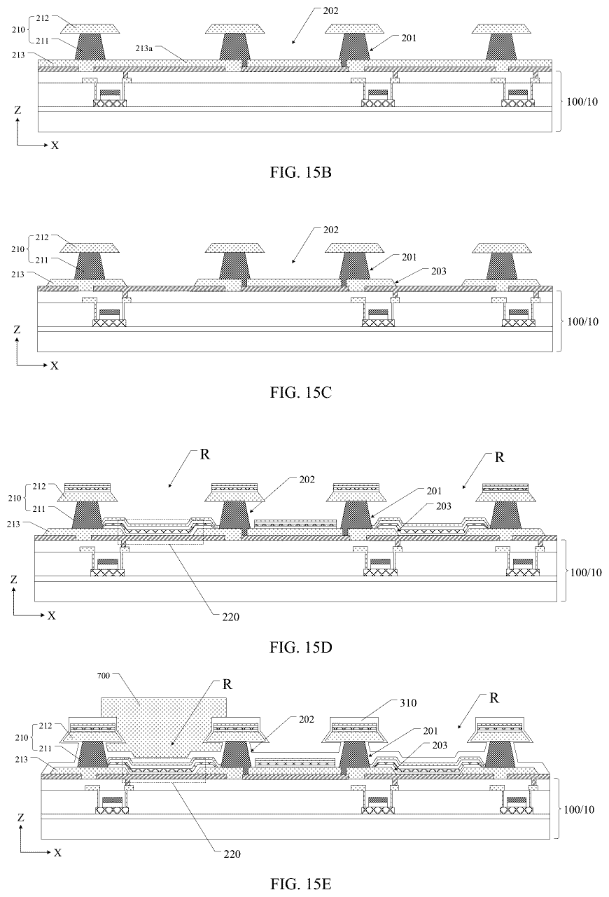

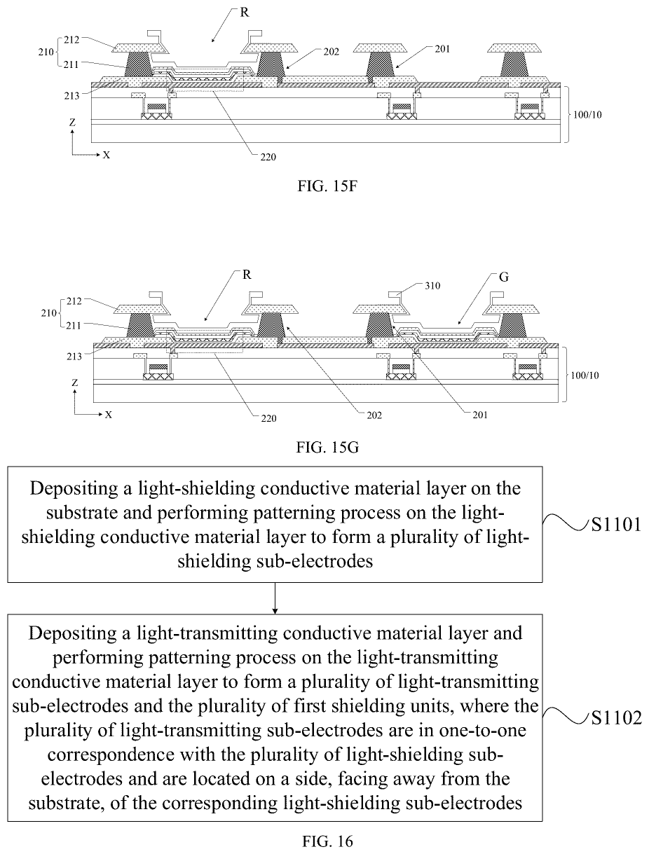

In the present disclosure, by providing an isolation structure at gaps between adjacent light-emitting devices (the “light-emitting unit” below), the functional film layers of adjacent light-emitting devices are separated. Therefore, in the evaporation process of the functional film layers, only full-surface evaporation on the display panel is needed, and there is no need to use a mask plate to prepare the functional film layer of each light-emitting device separately. There is no need to consider the issue of alignment accuracy during evaporation in the process, so that the gap between the light-emitting devices may be designed to be smaller in size to increase PPI (the principle may be seen in the relevant embodiments related to FIGS. 15A to 15G below).

Patents including No. PCT/CN2023/134518, No. 202310759370.2, No. 202310740412.8, No. 202310707209.0 and No. 202311346196.5 record the relevant technical solutions of the isolation structure, and their contents are incorporated herein by reference into the present disclosure for reference.

In some application scenarios, the display panel needs to have functions such as transparent display and under-screen recognition (fingerprint recognition, under-screen camera) based on application requirements. Therefore, a light-transmitting area will be designated within the display panel, and light-transmitting holes will be provided at the gaps of sub-pixels in the light-transmitting area to achieve light transmittance. However, in the area where the light-transmitting holes are located, the original light-blocking conductive structure in the display panel will be removed due to the requirement of light transmittance, which may cause signal interference in this area due to the lack of the conductive structure, resulting in poor display function.

At least one embodiment of the present disclosure provides a display panel and a display device to at least solve the above-mentioned technical problems. The display panel includes a substrate, and a display functional layer, an isolation structure, a pixel defining layer, and a shielding layer located on the substrate. The display functional layer includes a plurality of light-emitting devices located on the substrate. The isolation structure is located on the substrate, and defines a plurality of light-transmitting openings and a plurality of isolation openings. The pixel defining layer is located between the isolation structure and the substrate, and includes a plurality of pixel openings in one-to-one correspondence with the plurality of isolation openings. The isolation opening and the pixel opening are configured to confine the light-emitting device. That is, the isolation opening communicates with the pixel opening, and the light-emitting device is formed in the isolation opening and the pixel opening. The shielding layer includes a plurality of first shielding units located between the pixel defining layer and the substrate, and the first shielding unit corresponds to at least part of the light-transmitting openings. An orthographic projection of the first shielding unit on the substrate at least partially overlaps with an orthographic projection of the corresponding light-transmitting opening on the substrate. A through hole is provided in the pixel defining layer, and the first shielding unit is connected to the isolation structure through the through hole. In this display panel, shielding at the light-transmitting opening may be provided by the shielding layer to avoid signal interference while ensuring the light transmittance of the light-transmitting opening.

For example, in some scenarios, the display panel needs to have both touch function while also considering transparent display, under-screen recognition (fingerprint recognition, under-screen camera), and other features. Therefore, a light-transmitting area will be designated within the display panel, and light-transmitting holes will be provided at the gaps of sub-pixels in the light-transmitting area to achieve light transmittance. However, in the area where the light-transmitting holes are located, the signal interference may occur between the conductive structure used to achieve touch function (such as the “touch electrode” below) and the underlying driving circuit (such as the “pixel driving circuit in the substrate” below), resulting in poor touch function or display function.

In the following, a detailed explanation of a structure of a display panel according to at least one embodiment of the present disclosure will be provided with reference to the accompanying drawings. Additionally, in these accompanying drawings, a spatial rectangular coordinate system is established based on the substrate (or display substrate) of the display panel to intuitively present the positional relationship of various components within the display panel. In this spatial rectangular coordinate system, the X-axis and Y-axis are parallel to a plane of the substrate, while the Z-axis is perpendicular to the plane of the substrate.

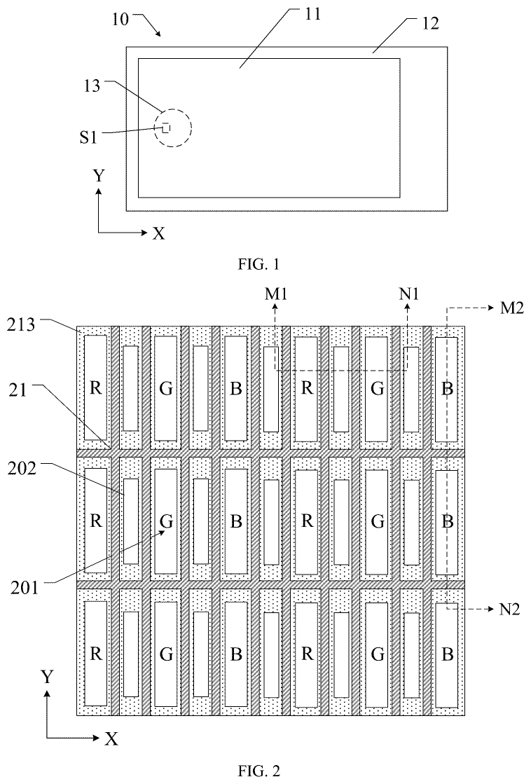

As shown in FIGS. 1 to 4, the display panel 10 includes a display area 11 and a non-display area 12 surrounding the display area 11. The display area 11 includes a first area 13, and sub-pixels emitting different colored light, such as R, G, B, are arranged in the display area 11. A plurality of light-transmitting openings 202 are provided in the first area 13, and the light-transmitting opening 202 enables the first area 13 to have a certain light transmittance for under screen recognition, imaging, or transparent display. In some embodiments of the present disclosure, some wiring in the non-display area 12 may be arranged in the display area 11, so that the non-display area 12 may be designed as a single-sided frame.

A physical structure of the display panel 10 includes a substrate 100 and a display functional layer, a touch structure 20, a shielding layer 30, and a pixel defining layer 213 provided on the substrate 100.

In an embodiment of the present disclosure, a circuit structure may be provided in the substrate for driving functional structures that used to achieve display or other functions (such as fingerprint recognition). These functional structures may be designed based on the application requirements of the produced display panels, which are not specifically limited here. Correspondingly, the specific design and type of circuit structures in the substrate are not specifically limited. For example, in at least one embodiment of the present disclosure, the substrate 100 may include a base and a driving circuit layer located on the base. The driving circuit layer includes a plurality of pixel driving circuits located within the display area, and the display functional layer is located on the driving circuit layer. For example, a pixel driver circuit may include a plurality of transistors (TFTs), capacitors, and so on, forming various forms such as 2T1C (i.e. 2 transistors (TFTs) and 1 capacitor (C)), 3T1C, or 7T1C. The pixel driver circuit is connected to the light-emitting device 220 to control an on/off state and brightness of the light-emitting device 220.

For example, the display functional layer includes a plurality of light-emitting devices 220 arranged on the substrate 100, and the light-emitting devices 220 are physical light-emitting structure of sub-pixels R, G, B.

For example, the isolation structure 210 is located on the substrate 100 and defines a plurality of light-transmitting openings 202 and a plurality of isolation openings 201. The plurality of light-emitting devices 220 are respectively confined in the plurality of isolation openings 201, and the plurality of light-transmitting opening 202 are arranged in the first area 13 and is located at gaps between the plurality of light-emitting devices 220, that is, the gaps between the plurality of light-emitting devices 220 are provided with the plurality of light-transmitting openings 202 for light transmittance. A mask plate may not be needed in the preparation process of the light-emitting device 220 due to application of the isolation structure 210, so that there is no need to consider the issue of alignment accuracy, which is beneficial for reducing a gap size of the light-emitting devices 220 and improving the pixel PPI of the display panel 10 (the principle may be seen in the relevant embodiments related to FIGS. 15A to 15G below). In addition, in the first area 13, by providing the light-transmitting opening 202 in the isolation structure 210, an area, where the light-transmitting opening 202 is disposed, of the display panel 10 may be light-transmitting, so that the first area 13 of the display panel 10 may achieve transparent display or under-screen recognition functions such as fingerprint recognition, under-screen camera, and so on.

For example, the touch structure 20 is located on a side, away from the substrate 100, of the display functional layer, and the touch structure 20 may include a touch electrode 400.

For example, the shielding layer 30 is located between the touch structure 20 and the substrate 100, and an orthographic projection of the light-transmitting opening 202 on the substrate 100 at least partially overlaps with an orthographic projection of the shielding layer 30 on the substrate 100.

For example, a material of the shielding layer 30 is a transparent conductive material. For example, the transparent conductive material may be indium tin oxide (ITO), indium gallium oxide (IGO), indium zinc oxide (IZO), and so on. Alternatively, the transparent conductive material may be a metal or metal alloy material with a thinner thickness, and the metal materials may be silver, aluminum, and so on. When the thickness is very thin, such as 100 nanometers or below 50 nanometers, these materials may transmit visible light and thus possess transparency properties.

The pixel defining layer 213 is located between the isolation structure 210 and the substrate 100, and includes a plurality of pixel openings 203 in one-to-one correspondence with the plurality of isolation openings 201. The pixel opening 203 is in communication with the corresponding isolation opening 201, so that the pixel opening 203 and the isolation opening 201 are configured to confine the light-emitting device 220.

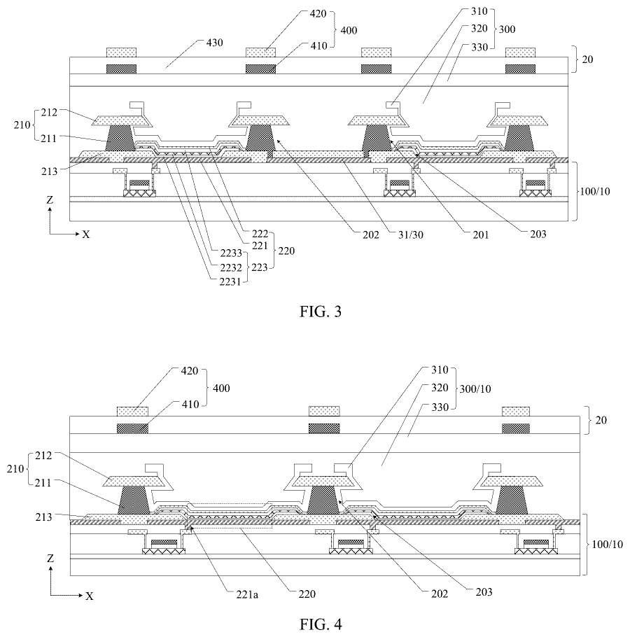

In at least one embodiment of the present disclosure, as shown in FIGS. 3 and 4, the orthographic projection of the light-transmitting opening 202 on the substrate 100 is located within an orthographic projection of a first shielding unit 31 of the shielding layer 30 on the substrate 100. Therefore, the shielding effect of the shielding layer 30 on the driving signal between the touch electrode 400 and the driving circuit layer may be further improved.

In the embodiment of the present disclosure, the specific structure of the touch electrode is not limited, and it can be designed according to the actual process requirements. In the following, different designs of the touch electrode will be illustrated through different embodiments as follows.

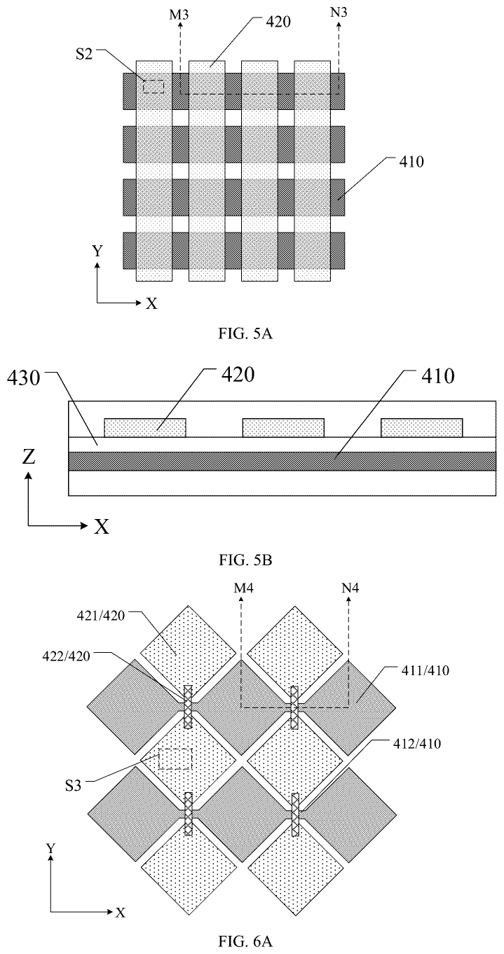

In at least one embodiment of the present disclosure, as shown in FIGS. 5A and 5B, the touch electrode 400 includes a plurality of parallel first electrode strips 410 and a plurality of parallel second electrode strips 420. The first electrode strip 410 and the second electrode strip 420 are spaced apart. An orthographic projection of the first electrode strip 410 on the substrate 100 and an orthographic projection of the second electrode strip 420 on the substrate 100 intersects with each other to form a touch unit at the intersection area, and the plurality of first electrode strips 410 and the plurality of second electrode strips 420 are arranged as grid-shaped electrodes.

For example, in some embodiments of the present disclosure, as shown in FIGS. 5A and 5B, the first electrode strip 410 is located between the second electrode strip 420 and the isolation structure 210. On a macro level, the intersection area where the first electrode 410 overlaps with the second electrode 42 is an area where the touch unit is located. And in this overlapping area, both the first electrode 410 and the second electrode 420 appear transparent. The first electrode strip 410 and the second electrode strip 420 may be separated by an insulation layer 430.

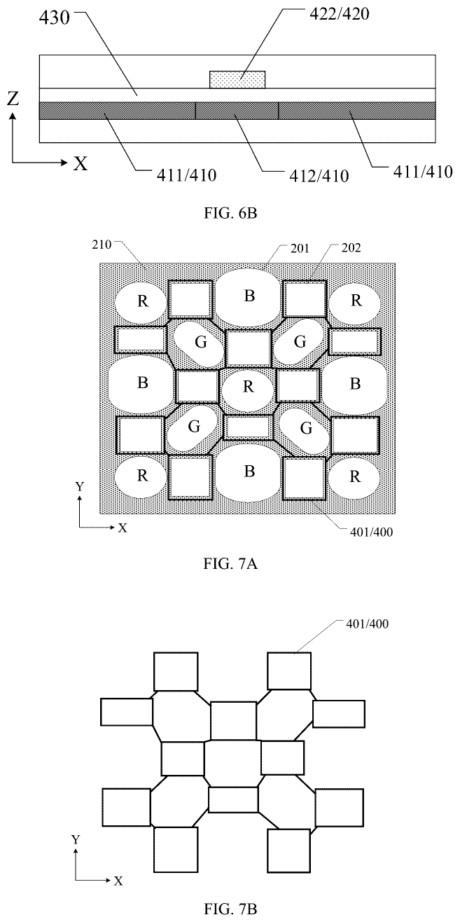

For example, in other embodiments of the present disclosure, as shown in FIGS. 6A and 6B, the first electrode strip 410 includes a plurality of first electrode blocks 411 spaced apart and a plurality of first connection portions 412. The plurality of first electrode blocks 411 of a same first electrode strip 410 are connected through the plurality of first connection portions 412. The second electrode strip 420 includes a plurality of second electrode blocks 421 and a plurality of second connection portions 422. The plurality of second electrode blocks 421 of a same second electrode strip 420 are connected through the plurality of second connection portions 422. An orthographic projection of the first connection portion 412 on the substrate 100 and An orthographic projection of the second connection portion 422 on the substrate 100 intersect with each other, and the first connection portion 412 and the second connection portion 422 are spaced apart from each other. The first electrode block 411, the first connection portion 412 and the second electrode strip 420 are located on a same layer, and the second connection portion 422 is located between the first connection portion 412 and the isolation structure 210, or the second connection portion 422 is located on the side of the first connection portion 412 away from the isolation structure 210. Under this design, the touch electrode 400 has a high transmittance, and the alignment accuracy between grid holes and the light-transmitting opening 202 and the isolation opening 201 is high, which may improve the light transmittance of the first area 13. In this design, the first electrode strip 410 and a main body of the second electrode strip 420 are designed on the same layer, so that there is no need to consider the alignment of their grid holes. Thus, the light transmittance of the touch electrode 400 may be improved. For example, the second connection portion 422 and the first connection portion 412 may be separated by the insulation layer 430.

In the embodiment of the present disclosure, a specific shape of the grid-shaped touch electrode 400 may be designed according to a pixel layout. For example, according to a pixel layout, as shown in FIG. 2, the arrangement of sub-pixels may be presented in multiple rows and columns. In each row, sub-pixels R G. B are arranged alternately in sequence. For example, according to another pixel layout, as shown in FIGS. 7A and 7B, the pixel layout structure includes a plurality of first sub-pixels R, a plurality of second sub-pixels G, and a plurality of third sub-pixels B. Wavelengths of light emitted from the first sub-pixel R, the second sub-pixel G, and the third sub-pixel B decreases sequentially, and the first sub-pixel R, the second sub-pixel G, and the third sub-pixel B are arranged in multiple rows and columns. The first sub-pixel R and the third sub-pixel B are arranged in a same row and a same column; in the rows and columns where the first sub-pixels R are arranged, the first sub-pixels R and the third sub-pixels B are arranged alternately. The rows where the first sub-pixels R and the third sub-pixels B are arranged and the rows where the second sub-pixels G are arranged are arranged alternately, and the columns where the first sub-pixels R and the third sub-pixels B are arranged and the columns where the second sub-pixels G are arranged are arranged alternately. Edges at the opposite ends of at least one of the first sub-pixel R, the second sub-pixel G and the third sub-pixel B are curved. For example, in the pixel layout structure shown in FIGS. 7A and 7B, a contour of the first sub-pixel R is circular, while contours of the second sub-pixel G and the third sub-pixel B both include two parallel edges and two semicircular arc edges. The first sub-pixel R has a first axis of symmetry passing through two semicircular arc edges, the second sub-pixel G has a second axis of symmetry passing through two semicircular arc edges, the first axis of symmetry is parallel to an extension direction of the column where the first sub-pixel R is located, the second axis of symmetry crosses the extension directions of the row and column, and the second axis of symmetry of the second sub-pixel G passes through centroids of two adjacent third sub-pixels B located in adjacent columns. As for the second sub-pixels G in the same column, the adjacent second sub-pixels G is axisymmetric, and the direction of the axis of symmetry is parallel to the direction of the row.

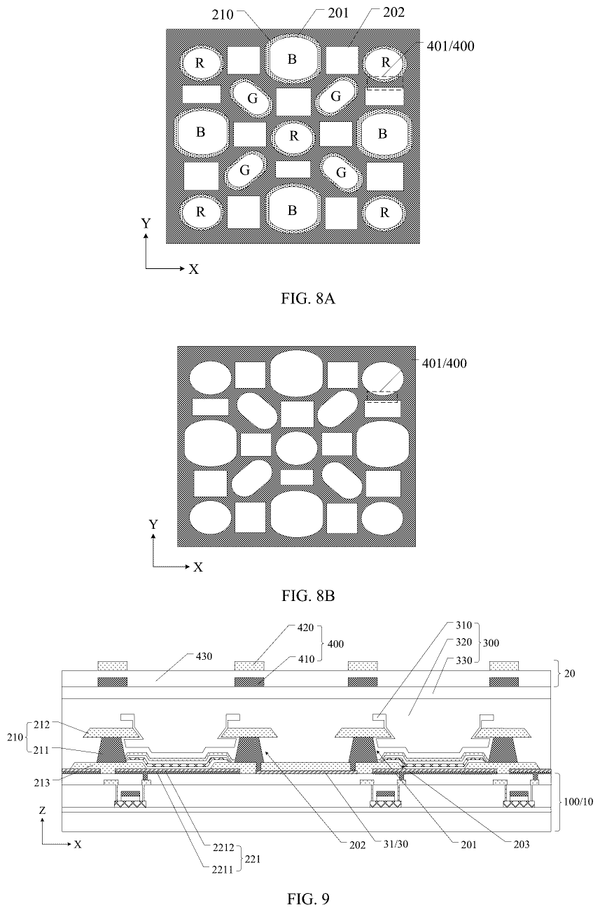

For example, in some embodiments of the present disclosure, as shown in FIGS. 7A and 7B, widths of line segment 401 at each position of the touch electrode 400 is the same; or in other embodiments, as shown in FIGS. 8A and 8B, the edge shape of the line segment 401 of the touch electrode 400 is conformal to the adjacent isolation opening 201 and light-transmitting opening 202, so that the maximum viewing angle of the light-emitting device in different directions (obstructed by the grid line) is roughly equal, thereby alleviating color deviation issue.

In at least one embodiment of the present disclosure, as shown in FIG. 9, the light-emitting device 220 includes a first electrode 221, a light-emitting functional layer 223, and a second electrode 222 sequentially stacked on the substrate 100. The light-emitting functional layer 223 and the second electrode 222 are located in the corresponding isolation opening 201 and pixel opening 203, and the first electrode 221 is located between the pixel defining layer 213 and the substrate 100.

For example, the first electrode 221 may be an anode, and the second electrode 222 may be a cathode.

For example, the light-emitting functional layer 223 may include a first common layer 2231, a light-emitting layer 2232, and a second common layer 2233. The first common layer 2231, the light-emitting layer 2232, and the second common layer 2233 are sequentially stacked on the first electrode 221. The first common layer 2231 may include a hole injection layer, a hole transport layer, an electron blocking layer, and so on. The second common layer 2232 may include an electron injection layer, an electron transport layer, a hole blocking layer, and so on. The setting of the isolation structure 210 allows the first common layers 221 (the main film layer causing current crosstalk) of each light-emitting device 220 to be electrically isolated from each other.

In at least one embodiment of the present disclosure, as shown in FIG. 9, at least part of the first electrode 221 is located on a same layer as the first shielding unit 31 and is composed of a same material as the first shielding unit 31. Thus, during the preparation of the first electrode 221, the first shielding unit 31 may be prepared at the same time, thereby simplifying the preparation process of the shielding layer 30 and controlling the preparation cost of the display panel.

In at least one embodiment of the present disclosure, as shown in FIG. 9, the first electrode 221 includes a light-shielding sub-electrode 2211 and a light-transmitting sub-electrode 2212 stacked in sequence, and the first shielding unit 31 is located on a same layer as the light-transmitting sub-electrode 2212 and is composed of a same material as the light-transmitting sub-electrode 2212.

In at least one embodiment of the present disclosure, as shown in FIG. 9, the light-shielding sub-electrode 2211 is located between the light-transmitting sub-electrode 2212 and the substrate 100. For example, the light-transmitting sub-electrode 2212 may be a high work function material such as ITO (Indium Tin Oxide), which may serve as an anode for the light-emitting device.

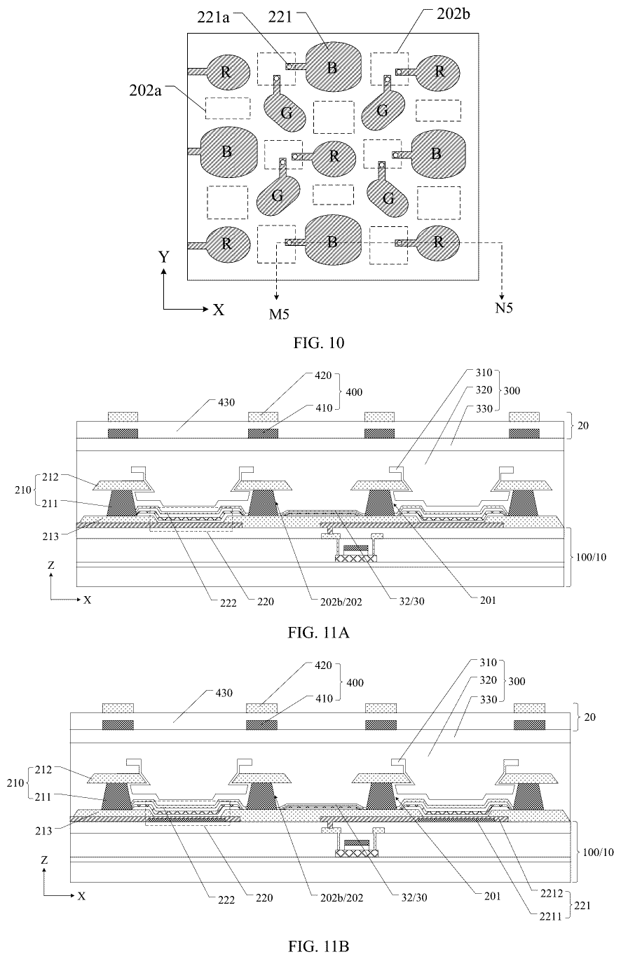

In at least one embodiment of the present disclosure, as shown in FIGS. 9 and 10, the substrate 100 includes a plurality of pixel driving circuits respectively corresponding to the plurality of light-emitting devices, and the pixel driving circuit is in contact with the first electrode 221 of the corresponding light-emitting device (at 221a). For example, the pixel driver circuit may include a plurality of transistors (TFTs), capacitors, and so on, forming various forms such as 2T1C (i.e. 2 transistors (TFTs) and 1 capacitor (C)), 3T1C, or 7T1C. The pixel driver circuit is connected to the light-emitting device 220 to control the on/off state and brightness of the light-emitting device 220.

In some embodiments of the present disclosure, the plurality of light-transmitting openings 202 are in one-to-one correspondence with the plurality of first shielding units 31. An orthographic projection of an area, where the pixel driver circuit is in contact with the first electrode 221, on the substrate 100 is located outside an orthographic projection of the light-transmitting opening 202 on the substrate 100. That is, the layout of the light-transmitting opening 202 is designed to avoid a contact area between the pixel driving circuit and the first electrode 221. In this way, it can be ensured that the area of the display panel corresponding to the light-transmitting opening 202 has a high light transmittance, and the shielding layer 30 may be formed by the plurality of first shielding units 31. That is, during the preparation of the first electrode 221, the entire shielding layer 30 may be prepared at the same time.

In other embodiments of the present disclosure, as shown in FIGS. 10 and 11A, the light-transmitting opening 202 is divided into a first-type light-transmitting opening 202a and a second-type light-transmitting opening 202b. An orthographic projection of a contact area between the pixel driving circuit and the first electrode 221 on the substrate 100 is located outside an orthographic projection of the first-type light-transmitting opening 202a on the substrate 100, and is located within an orthographic projection of the second-type light-transmitting opening 202b on the substrate 100. The shielding layer 30 further includes a plurality of second shielding units 32, the second shielding unit 32 is connected to the isolation structure 210. The first shielding unit 31 corresponds to the first-type light-transmitting opening 202a, the second shielding unit 32 corresponds to the second-type light-transmitting opening 202b, and the second shielding unit 32 is located on a side, away from the substrate 100, of the pixel defining layer 213. In this way, the second shielding unit 32 can be designed to avoid occupying the layout space for the aforementioned contact area.

In at least one embodiment of the present disclosure, an orthographic projection of the second-type light-transmitting opening 202b on the substrate 100 is located within an orthographic projection of an orthographic projection of the corresponding second shielding unit 32 on the substrate 100.

In at least one embodiment of the present disclosure, in the structures shown in FIGS. 10 and 11A, the second shielding unit 32 is located on a same layer and is composed of a same material as the second electrode 222, so that the second shielding unit 32 may transmit light. In this way, during the preparation of the second electrode 222, the second shielding unit 32 may be prepared at the same time, thereby simplifying the preparation process of the second shielding unit 32. That is, during the preparation of the first electrode and the second electrode 222, the entire shielding layer 30 may be prepared at the same time, so that the preparation of the shielding layer 30 does not increase the preparation process of the display panel, thereby controlling the preparation cost of the display panel.

For example, the light transmittance of the first shielding unit 31 is greater than the light transmittance of the second shielding unit 32.

In some embodiments of the present disclosure, as shown in FIG. 9, in a case where the first electrode 221 includes a light-shielding sub-electrode 2211 and a light-transmitting sub-electrode 2212 stacked in sequence, an orthographic projection of the light-shielding sub-electrode 2211 on the substrate 100 coincides with an orthographic projection of the light-transmitting sub-electrode 2212 on the substrate 100. And in the contact area, the first electrode 221 is connected to the pixel driving circuit through the light-shielding sub-electrode 2211. The light-shielding sub-electrode 2211 may be a metal film layer, while the light-transmitting sub-electrode 2212 needs to be a high work function material to ensure transparency, as it needs to include oxide materials such as indium tin oxide. The conductivity of the light-shielding sub-electrode 2211 is generally higher than the conductivity of the light-transmitting sub-electrode 2212, which can reduce the impedance at the contact area.

In other embodiments of the present disclosure, as shown in FIGS. 10 and 11B, in a case where the first electrode 221 includes a light-shielding sub-electrode 2211 and a light-transmitting sub-electrode 2212 stacked in sequence, an orthographic projection of the light-shielding sub-electrode 2211 on the substrate 100 is located within an orthographic projection of the light-transmitting sub-electrode 2212 on the substrate 100, and the orthographic projection of the light-shielding sub-electrode 2211 on the substrate 100 is located outside the orthographic projection of the second-type light-transmitting opening 202b on the substrate 100. An orthographic projection of a part of the light-transmitting sub-electrode 2212 on the substrate is located within the orthographic projection of the second-type light-transmitting opening 202b, so that the light-transmitting sub-electrode 2212 may be in contact with the pixel driving circuit. In this way, the contact area between the first electrode 221 and the second-type light-transmitting opening 202b can be made transparent, further improving the light transmittance of the second-type light-transmitting opening 202b.

In at least one embodiment of the present disclosure, referring back to FIGS. 2 and 3, a gap between adjacent light-emitting devices 220 (such as corresponding sub-pixels R and G) is a first gap, a gap between the light-emitting device 220 and the light-transmitting opening 202 adjacent to the light-emitting device 220 is a second gap, and the touch electrode 400 may be designed as a grid-shaped electrode. An orthographic projection of grid lines of the grid-shaped electrode are located within an orthographic projection of the first gap on the substrate 100, and within an orthographic projection of the second gap on the substrate 100. That is, in the touch electrode 400, an orthographic projection of a part of the grid lines 21 on the substrate 100 is located within an orthographic projection of orthographic projection of the gaps between the sub-pixels, and an orthographic projection of another part of the grid lines 21 on the substrate 100 is located within an orthographic projection of the gap between the sub-pixel and the light-transmitting opening 202 on the substrate 100. This design may increase the light transmittance of the touch electrode 400 and enable the use of high conductivity materials such as metals as the material of the touch electrode 400.

In at least one embodiment of the present disclosure, as shown in FIG. 11A, the isolation structure 210 includes a support portion 211 and a crown portion 212 sequentially stacked on the substrate 100. On a side of the isolation structure 210 facing the light-transmitting opening 202, an orthographic projection of the edge of the support portion 211 on the substrate 100 is located within an orthographic projection of the edge of the crown portion 212 on the substrate 100. That is, the edge of the crown portion 212 extends beyond the edge of the support portion 211. In this way, in the evaporation process of the film layers (such as “light-emitting functional layer” and “second electrode” below) of the light-emitting device, the evaporation range of these film layers may be limited by the crown portion 212, so that some film layers (such as “light-emitting functional layer” below) are separated by the isolation structure 210 while ensuring that other film layers (such as “second electrode” below) are connected to the isolation structure 210.

For example, the support portion 211 is a conductive structure, the light-emitting functional layer 223 and the second electrode 222 of the light-emitting device 220 are located in the corresponding isolation opening 201, and the second electrode 222 of the light-emitting device 220 is located in the corresponding isolation opening 201 and connected to the support portion 211. In this way, the second electrodes 230 of each light-emitting device 220 are connected through the support portion 211 to form a common electrode, and the support portion 211 may be not limited by thickness, thereby reducing the impedance of the common electrode.

For example, the shielding layer 30 is connected to the support portion 211. In this way, it can avoid the disconnection of the common electrode at the light-transmitting opening 202, and further reduce the impedance of the common electrode.

A material of the second electrode 222 may be a metal material. The smaller the thickness of the second electrode 222 is, the higher the light transmittance of the second electrode 222 will be, but the higher the resistivity of the second electrode 222 will be. However, if the thickness of the second electrode 222 is too small, it will cause the pressure drop of the second electrode 222 (which is the common electrode at this time) to be too large without the isolation structure 210. In the embodiment of the present disclosure, the second electrode 222 is connected to the conductive support portion 211, which may remove the thickness limit of the second electrode 222, so that the second electrode 222 has a smaller thickness to achieve a higher light transmittance.

In at least one embodiment of the present disclosure, the support portion 211 may be a metal conductive structure. As the conductivity of the metal material is high, the voltage drop may be reduced when driving the cathode. Correspondingly, the metal material can only transmit light when their thickness is extremely thin (such as at the tens of nanometers scale), while the isolation structure 210 requires a certain thickness to separate the light-emitting functional layers 223 (which includes the first common layer 2231). Correspondingly, the support portion 211 in the isolation structure 220 is almost opaque. Therefore, only by setting a light-transmitting opening 202 can the isolation structure 210 transmit light.

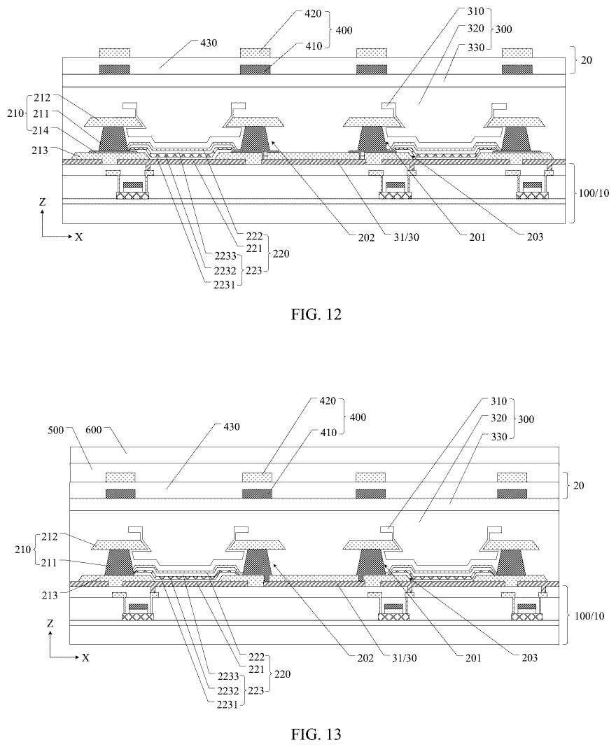

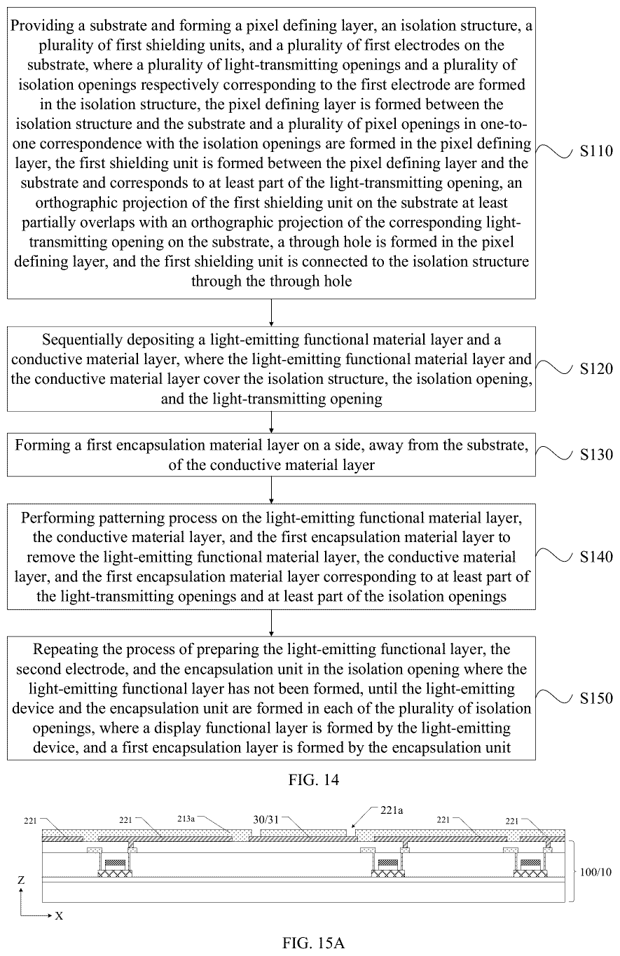

In at least one embodiment of the present disclosure, as shown in FIG. 12, the isolation structure 210 further includes an auxiliary support portion 214. The auxiliary support portion 214 is located on a side, away from the crown portion 212, of the support portion 211 and is a conductive structure. An orthographic projection of the auxiliary support portion 214 on the substrate 100 is located within an orthographic projection of the crown portion 212 on the substrate 100; an orthographic projection of the support portion 211 on the substrate 100 is located within the orthographic projection of the auxiliary support portion 214 on the substrate 100. The part of the surface, facing away from the substrate 100 and not covered by the support portion 211, of the auxiliary support portion 214 may be configured to be in contact with the second electrode 222. Compared to the sidewall of the support portion 211, a deposition thickness of the second electrode 222 on the surface of the auxiliary support portion 214 may be greater; therefore. Therefore, the auxiliary support portion 214 has a larger contact area and a larger bonding strength with the second electrode 222, thereby reducing the impedance between the second electrode 222 and the isolation structure 210.

For example, the crown portion 212, the support portion 211, and the auxiliary support portion 214 can be sequentially prepared from titanium, aluminum, and molybdenum. The corrosion resistance of titanium, molybdenum, and aluminum decreases sequentially, thus forming the isolation structure 210 as shown in FIG. 10.

For example, in a case where the auxiliary support portion 214 is provided, in the light-transmitting opening 202, the shielding layer 30 may be connected to the auxiliary support portion 214 through a through-hole in the pixel defining layer 213 to further reduce the impedance between the isolation structure 210 and the shielding layer 30.

In at least one embodiment of the present disclosure, as shown in FIG. 12, an encapsulation layer 300 may be provided between the display functional layer and the touch structure 20. For example, the encapsulation layer 300 includes a first encapsulation layer 310, the first encapsulation layer 310 includes a plurality of encapsulation units in one-to-one correspondence with the isolation openings 201, and the encapsulation unit covers the corresponding isolation opening 201. The light-emitting device 220 is prepared in batches based on different colors of emitting light, and the encapsulation unit is used for protecting the light-emitting device 220 in the preparation process. Therefore, the plurality of encapsulation units are also prepared in batches.

For example, the encapsulation layer 300 may further include a second encapsulation layer 320 and a third encapsulation layer 330 sequentially stacked on the first encapsulation layer 310, and the second encapsulation layer 320 is located between the first encapsulation layer 310 and the third encapsulation layer 330. For example, the first encapsulation layer 310 and the third encapsulation layer 330 are inorganic layers, with high compactness to isolate water and oxygen. The second encapsulation layer 320 is an organic layer as a planarization layer, which has a larger thickness to flatten the surface of the display panel, facilitating the preparation of structures such as the touch electrode 400 on the encapsulation layer 300.

The first encapsulation layer 310 may be used for protecting the light-emitting device 220 in the preparation process, that is, during the preparation of the light-emitting device 220, the first encapsulation layer 310 may be formed at the same time. For details, the relevant embodiments related to FIGS. 15A to 15G may be referred to in the following, which are not described herein.

For example, as shown in FIG. 12, the display panel may further include structures such as an optical film 500, a cover plate 600, and so on, and these structures may be located on a side, away from the display functional layer, of the touch structure 20.

At least one embodiment of the present disclosure provides a manufacturing method for a display panel, as shown in FIG. 13, the manufacturing method includes steps S110 to S150 as follows.

Step S110: providing a substrate and forming a pixel defining layer, an isolation structure, a plurality of first shielding units, and a plurality of first electrodes on the substrate, where a plurality of light-transmitting openings and a plurality of isolation openings respectively corresponding to the first electrode are formed in the isolation structure, the pixel defining layer is formed between the isolation structure and the substrate and a plurality of pixel openings in one-to-one correspondence with the isolation openings are formed in the pixel defining layer, the first shielding unit is formed between the pixel defining layer and the substrate and corresponds to at least part of the light-transmitting openings, an orthographic projection of the first shielding unit on the substrate at least partially overlaps with an orthographic projection of the corresponding light-transmitting opening on the substrate, a through hole is formed in the pixel defining layer, and the first shielding unit is connected to the isolation structure through the through hole.

Step S120: sequentially depositing a light-emitting functional material layer and a conductive material layer, where the light-emitting functional material layer and the conductive material layer cover the isolation structure, the isolation opening, and the light-transmitting opening.

Step S130: forming a first encapsulation material layer on a side, away from the substrate, of the conductive material layer.

Step S140: performing patterning process on the light-emitting functional material layer, the conductive material layer, and the first encapsulation material layer to remove the light-emitting functional material layer, the conductive material layer, and the first encapsulation material layer corresponding to at least part of the light-transmitting openings and at least part of the isolation openings. A light-emitting functional layer is formed by the remaining light-emitting functional material layer, a second electrode is formed by the remaining conductive material layer, an encapsulation unit is formed by the remaining first encapsulation material layer, and a light-emitting device is formed by the light-emitting functional layer, the second electrode, and the first electrode corresponding to the isolation opening where the light-emitting functional layer and the second electrode are located.

Step S150: repeating the process of preparing the light-emitting functional layer, the second electrode, and the encapsulation unit in the isolation opening where the light-emitting functional layer has not been formed, until the light-emitting device and the encapsulation unit are formed in each of the plurality of isolation openings, where a display functional layer is formed by the light-emitting device, and a first encapsulation layer is formed by the encapsulation unit.

The display panel obtained from steps S110 to S150 above can be seen in FIG. 3 or FIG. 4. The specific process steps may be found in the relevant explanations of the embodiments shown in FIGS. 15A to 15G below, and the details are not described herein.

For example, in an example, the first electrode includes a light-shielding sub-electrode and alight-transmitting sub-electrode stacked in sequence, and the step S110: providing a substrate and forming a pixel defining layer, an isolation structure, a plurality of first shielding units, and a plurality of first electrodes on the substrate, as shown in FIG. 16, may include the following steps.

Step S1101: depositing a light-shielding conductive material layer on the substrate and performing patterning process on the light-shielding conductive material layer to form a plurality of light-shielding sub-electrodes.

Step S1102: depositing a light-transmitting conductive material layer and performing patterning process on the light-transmitting conductive material layer to form a plurality of light-transmitting sub-electrodes and the plurality of first shielding units, where the plurality of light-transmitting sub-electrodes are in one-to-one correspondence with the plurality of light-shielding sub-electrodes and are located on a side, facing away from the substrate, of the corresponding light-shielding sub-electrodes. The display panel obtained from this manufacturing method can be seen in the relevant embodiments shown in FIGS. 3 and 4 above, and the details are not described herein.

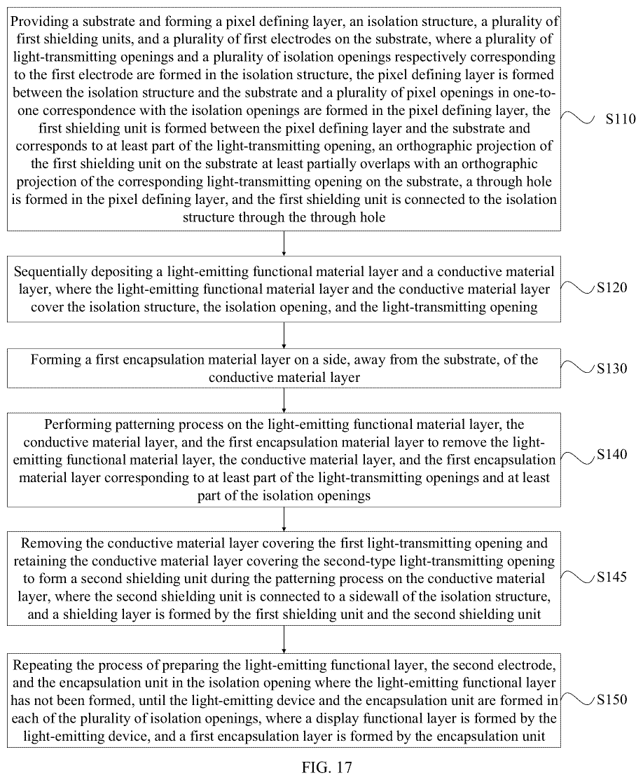

For example, in another example, the light-transmitting openings includes a first-type light-transmitting opening and a second-type light-transmitting opening, the first shielding unit corresponds to the first-type light-transmitting opening, as shown in FIG. 17, the manufacturing method further includes the following steps.

Step S145: removing the conductive material layer covering the first light-transmitting opening and retaining the conductive material layer covering the second-type light-transmitting opening to form a second shielding unit during the patterning process on the conductive material layer, where the second shielding unit is connected to a sidewall of the isolation structure, and a shielding layer is formed by the first shielding unit and the second shielding unit. The display panel obtained from this manufacturing method can be seen in the relevant embodiment shown in FIG. 10 above, and the details are not described herein.

In the following, the preparation process of the display panel shown in FIG. 3 will be described with reference to FIGS. 15A to 15G to visually demonstrate the principle that the isolation structure can increase the pixel layout density PPI.

As shown in FIG. 15A, a substrate 100 is provided and a plurality of first electrodes 221 are formed and arranged in an array on the substrate 100. Then plurality of first shielding units 31 (or the entire shielding layer 30) are formed. An insulation material film layer 213a (such as an inorganic material film layer) is deposited, and a patterning process is performed to form a plurality of through-holes 221a in the insulation material film layer 213a.

In the embodiment of the present disclosure, the patterning process may be a photolithography patterning process, for example, including: coating photoresist on a structural layer to be composed, exposing the photoresist with a mask plate, developing the exposed photoresist to obtain a photoresist pattern, etching the structural layer with the photoresist pattern (either wet or dry etching is available), and then optionally removing the photoresist pattern. In a case where the material of the structural layer (such as “photoresist pattern 700” below) includes photoresist, the structural layer may be directly exposed with a mask plate to form the desired pattern.

As shown in FIG. 15B, a plurality of support portions 211 and a plurality of crown portions 212 are formed on the insulation material film layer 213a, and a plurality of light-transmitting openings 202 and plurality of isolation openings 201 are defined in it.

As shown in FIG. 15C, a patterning process is performed on the insulation material film layer to form a pixel defining layer 213 (with a grid like planar shape). The pixel defining layer 213 includes a pixel opening 203 and covers gaps between adjacent first electrodes. In this way, the planer shape of the pixel defining layer 213 is grid-shaped.

As shown in FIG. 15D, a light-emitting functional layer and a second electrode are evaporated on the substrate 100 to form a light-emitting device 220 in each isolation opening 201 of the isolation structure 210. A mask plate is not used in the evaporation process, so the evaporated material will also deposit on the crown 212, as well as in the light-transmitting opening 202 and the isolation opening 201. For example, the evaporated light-emitting functional layer may emit red light (R), that is, at this step, each light-transmitting opening 202 and isolation opening 201 of the isolation structure 210 form a light-emitting device 220 that emits red light.

As shown in FIG. 15E, a first encapsulation layer 310 is deposited to cover the light-emitting device 220. At this step, the first encapsulation layer 310 may cover the entire display area. A photoresist (such as coating) is formed on the first encapsulation layer 310, and then a patterning process is performed on the photoresist to form a photoresist pattern 700. The photoresist pattern 700 only covers a part of the isolation opening 201 of the isolation structure 210 (the isolation opening 201 where the light-emitting device R of the prepared display panel is located).

As shown in FIG. 15F, the surface of the display panel is etched with the photoresist pattern 700 as a mask, and the first encapsulation layer 310, the second electrode, and the light-emitting functional layer that are not covered by the photoresist pattern 700 are removed. Then, the remaining photoresist pattern 700 is removed.

As shown in FIG. 15G, the above steps are repeated to respectively form light-emitting devices 220 that emitting green light (G) and blue light (not shown in the figure) in other isolation openings 201.

As shown in FIG. 3, after all the light-emitting devices 220 are prepared, a second encapsulation layer 320 is formed on the first encapsulation layer 310, a third encapsulation layer 330 is formed on the second encapsulation layer 320; and a touch electrode layer 400 is prepared on the third encapsulation layer 330.

The preparation sequence of the light-emitting devices 220 that respectively emit red, green, and blue light can be designed according to actual needs, and is not specifically limited here.

In some embodiments of the present disclosure, some film layers in the light-emitting functional layer, such as the light-emitting layer, may be prepared through non-deposition methods such as inkjet printing, and the specific method can be selected based on the material of these film layers. For example, in cases where these film layers are polymer materials that are not suitable for deposition, inkjet printing can be used for preparation.

In the embodiment of the present disclosure, the design area of the first area is not limited, and it can be designed based on the actual process requirements and the application scenarios of the display panel.

For example, in some embodiments of the present disclosure, the entire display area may be designed as the first area 13. Under this design, the display panel can be used in scenarios such as transparent display.

For example, in other embodiments of the present disclosure, as shown in FIG. 1, the display area further includes a second area (an area within the display area 11 and outside the first area 13). The second area may be located on at least one side of the first area 13. The first area 13 is a transparent area, and the second area is a non-transparent area. Under this design, the display panel can be used in scenarios such as fingerprint recognition or under-screen camera.

At least one embodiment of the present disclosure provides a display panel, and the display panel includes a display functional layer, an isolation structure, and a shielding layer located on the substrate. The display functional layer includes a plurality of light-emitting devices located on the substrate, and the light-emitting device includes a first electrode, a light-emitting functional layer, and a second electrode sequentially stacked on the substrate. The isolation structure is located on the substrate, and defines a plurality of light-transmitting openings and a plurality of isolation openings, where the isolation opening is configured to confine the light-emitting device, and the light-emitting functional layer and the second electrode are located in the corresponding isolation opening and the corresponding pixel opening. The shielding layer includes a plurality of first shielding units, where the first shielding unit corresponds to at least part of the light-transmitting openings, an orthographic projection of the first shielding unit on the substrate at least partially overlaps with an orthographic projection of the corresponding light-transmitting opening on the substrate. The first shielding unit is connected to the isolation structure, where at least part of the first electrode is located on a same layer as the first shielding unit and is composed of a same material as the first shielding unit. The specific structure of the display panel, the technical problems solved, the principles for solving technical problems, and further design structures may refer to the relevant explanations in the aforementioned embodiments, and details are not described herein again.

At least one embodiment of the present disclosure provides a display device, and the display device may include a display panel in the aforementioned embodiment. Furthermore, in a case where the first area is a recognition area, the display device may include a recognition device, and an orthographic projection of the recognition device on the substrate at least partially overlaps with the first area.

For example, in some embodiments of the present disclosure, the recognition device includes at least one fingerprint recognition sensor. For example, the fingerprint recognition sensor may be disposed on a side, away from the display functional layer, of the substrate, or the fingerprint recognition sensor may also be disposed within the substrate.

For example, in other embodiments of the present disclosure, the recognition device may be a camera, and the camera is located on the side, away from the display functional layer, of the substrate.

For example, in the embodiment of the present disclosure, the display device may be any product or component with display function, such as a television, a digital camera, a mobile phone, a watch, a tablet, a laptop, a navigation device, and so on.

The above embodiments are merely preferred embodiments of this specification and are not intended to limit it. Any modifications, equivalent substitutions, and so on, made within the spirit and principles of this specification, shall fall within the protection scope of this specification.

What is claimed is:

1. A display panel, comprising:
a substrate;
a display functional layer, comprising a plurality of light-emitting devices located on the substrate;
an isolation structure located on the substrate, defining a plurality of light-transmitting openings and a plurality of isolation openings;
a pixel defining layer located between the isolation structure and the substrate, comprising a plurality of pixel openings in one-to-one correspondence with the plurality of isolation openings, wherein the isolation opening and the pixel opening are configured to confine the light-emitting device; and
a shielding layer, comprising a plurality of first shielding units located between the pixel defining layer and the substrate, wherein the first shielding unit corresponds to at least part of the light-transmitting openings, and an orthographic projection of the first shielding unit on the substrate at least partially overlaps with an orthographic projection of the corresponding light-transmitting opening on the substrate, and
a through hole is provided in the pixel defining layer, and the first shielding unit is connected to the isolation structure through the through hole.

2. The display panel according to claim 1, wherein an orthographic projection of the light-transmitting opening is located within an orthographic projection of the corresponding first shielding unit on the substrate.

3. The display panel according to claim 1, wherein
The light-emitting device comprises a first electrode, a light-emitting functional layer, and a second electrode sequentially stacked on the substrate, the light-emitting functional layer and the second electrode are located in the corresponding isolation opening and the corresponding pixel opening, the first electrode is located between the pixel defining layer and the substrate, and
at least part of the first electrode is located on a same layer as the first shielding unit and is composed of a same material as the first shielding unit.

4. The display panel according to claim 3, wherein the first electrode comprises a light-shielding sub-electrode and a light-transmitting sub-electrode stacked in sequence, and the first shielding unit is located on a same layer as the light-transmitting sub-electrode and is composed of a same material as the light-transmitting sub-electrode; and
the light-shielding sub-electrode is located between the light-transmitting sub-electrode and the substrate.

5. The display panel according to claim 3, wherein the substrate comprises a plurality of pixel driving circuits respectively corresponding to the plurality of light-emitting devices, and the pixel driving circuit is in contact with the first electrode of the corresponding light-emitting device.

6. The display panel according to claim 5, wherein the plurality of light-transmitting openings are in one-to-one correspondence with the plurality of first shielding units, and an orthographic projection of an area, where the pixel driving circuit is in contact with the first electrode, on the substrate is located outside an orthographic projection of the light-transmitting opening on the substrate.

7. The display panel according to claim 5, wherein the plurality of light-transmitting openings comprise a first-type light-transmitting opening and a second-type light-transmitting opening, an orthographic projection of an area, where the pixel driving circuit is in contact with the first electrode, on the substrate is located outside an orthographic projection of the first-type light-transmitting opening on the substrate, and is located within an orthographic projection of the second-type light-transmitting opening on the substrate, and
the shielding layer further comprises a plurality of second shielding units, the second shielding unit is connected to the isolation structure, the first shielding unit corresponds to the first-type light-transmitting opening, the second shielding unit corresponds to the second-type light-transmitting opening, and the second shielding unit is located on a side, away from the substrate, of the pixel defining layer;
an orthographic projection of the second-type light-transmitting opening on the substrate is located within an orthographic projection of the corresponding second shielding unit on the substrate;
the second shielding unit is located on a same layer as the second electrode and is composed of a same material as the second electrode; and
the first electrode comprises a light-shielding sub-electrode and a light-transmitting sub-electrode stacked in sequence, an orthographic projection of the light-shielding sub-electrode on the substrate is located within an orthographic projection of the light-transmitting sub-electrode on the substrate, the orthographic projection of the light-shielding sub-electrode on the substrate is located outside the orthographic projection of the second-type light-transmitting opening on the substrate, and an orthographic projection of a part of the light-transmitting sub-electrode on the substrate is located within the orthographic projection of the second-type light-transmitting opening, for the part of the light-transmitting sub-electrode to be in contact with the pixel driving circuit.

8. The display panel according to claim 3, further comprising:
a touch structure located on a side, away from the substrate, of the display functional layer, wherein the touch structure comprises a touch electrode,
a gap between adjacent light-emitting devices is a first gap, and a gap between the light-emitting device and the light-transmitting opening adjacent to the light-emitting device is a second gap, and
the touch electrode is a grid-shaped electrode, and an orthographic projection of grid lines of the grid-shaped electrode on the substrate is located within an orthographic projection of the first gap on the substrate, and is located within an orthographic projection of the second gap on the substrate.

9. The display panel according to claim 3, wherein the isolation structure comprises a support portion and a crown portion, the support portion is located between the crown portion and the pixel defining layer, and
the support portion is a conductive structure, and the second electrode is connected to the support portion;
the shielding layer is connected to the support portion;
the isolation structure further comprises an auxiliary support portion, the auxiliary support portion is located on a side, away from the crown portion, of the support portion and is a conductive structure, wherein an orthographic projection of the auxiliary support portion on the substrate is located within an orthographic projection of the crown portion on the substrate, and an orthographic projection of the support portion on the substrate is located within the orthographic projection of the auxiliary support portion on the substrate; and
the shielding layer is connected to the auxiliary support portion.

10. The display panel according to claim 1, further comprising a first encapsulation layer, wherein the first encapsulation layer comprises a plurality of encapsulation units in one-to-one correspondence with the plurality of isolation openings, and the encapsulation unit covers the corresponding isolation opening;
a second encapsulation layer and a third encapsulation layer, covering the first encapsulation layer, the isolation structure, and the shielding layer, wherein the second encapsulation layer is located between the first encapsulation layer and the third encapsulation layer; and
a touch structure located on a side, away from the substrate, of the third encapsulation layer;
wherein the first encapsulation layer and the third encapsulation layer are inorganic layers, and the second encapsulation layer is an organic layer;
the second encapsulation layer is a planarization layer.

11. The display panel according to claim 1, wherein the display panel comprises a display area, the display area comprises a first area and a second area, the second area is located on at least one side of the first area, and the plurality of light-transmitting openings are located in the first area.

12. A display panel, comprising:
a substrate;
a display functional layer, comprising a plurality of light-emitting devices located on the substrate, wherein the light-emitting device comprises a first electrode, a light-emitting functional layer, and a second electrode sequentially stacked on the substrate;
an isolation structure located on the substrate, defining a plurality of light-transmitting openings and a plurality of isolation openings, wherein the isolation opening is configured to confine the light-emitting device, and the light-emitting functional layer and the second electrode are located in the corresponding isolation opening; and
a shielding layer, comprising a plurality of first shielding units, wherein the first shielding unit corresponds to at least part of the light-transmitting openings, an orthographic projection of the first shielding unit on the substrate at least partially overlaps with an orthographic projection of the corresponding light-transmitting opening on the substrate, and the first shielding unit is connected to the isolation structure, wherein
at least part of the first electrode is located on a same layer as the first shielding unit and is composed of a same material as the first shielding unit.

13. The display panel according to claim 12, further comprising a pixel defining layer, wherein the pixel defining layer is located between the isolation structure and the substrate, and comprises a plurality of pixel openings in one-to-one correspondence with the plurality of isolation openings, the isolation opening and the pixel opening are configured to confine the light-emitting device, a through hole is provided in the pixel defining layer, and the first shielding unit is connected to the isolation structure through the through hole;
the first electrode comprises a light-shielding sub-electrode and a light-transmitting sub-electrode stacked in sequence, and the first shielding unit is located on a same layer as the light-transmitting sub-electrode and is composed of a same material as the light-transmitting sub-electrode; and
the orthographic projection of the light-transmitting opening is located within the orthographic projection of the corresponding first shielding unit on the substrate.

14. The display panel according to claim 13, wherein the substrate comprises a plurality of pixel driving circuits respectively corresponding to the plurality of light-emitting devices, and the pixel driving circuit is in contact with the first electrode of the corresponding light-emitting device.

15. The display panel according to claim 14, wherein the plurality of light-transmitting openings are in one-to-one correspondence with the plurality of first shielding units, and an orthographic projection of an area, where the pixel driving circuit is in contact with the first electrode, on the substrate is located outside the orthographic projection of the light-transmitting opening on the substrate.

16. The display panel according to claim 14, wherein the plurality of light-transmitting openings comprise a first-type light-transmitting opening and a second-type light-transmitting opening, an orthographic projection of an area, where the pixel driving circuit is in contact with the first electrode, on the substrate is located outside an orthographic projection of the first-type light-transmitting opening on the substrate, and is located within an orthographic projection of the second-type light-transmitting opening on the substrate, and
the shielding layer further comprises a plurality of second shielding units, the second shielding unit is connected to the isolation structure, the first shielding unit corresponds to the first-type light-transmitting opening, the second shielding unit corresponds to the second-type light-transmitting opening, and the second shielding unit is located on a side, away from the substrate, of the pixel defining layer;
the orthographic projection of the second-type light-transmitting opening on the substrate is located within an orthographic projection of the corresponding second shielding unit on the substrate;
the second shielding unit is located on a same layer as the second electrode and is composed of a same material as the second electrode; and
the first electrode comprises a light-shielding sub-electrode and a light-transmitting sub-electrode stacked in sequence, an orthographic projection of the light-shielding sub-electrode on the substrate is located within an orthographic projection of the light-transmitting sub-electrode on the substrate, the orthographic projection of the light-shielding sub-electrode on the substrate is located outside the orthographic projection of the second-type light-transmitting opening on the substrate, and an orthographic projection of a part of the light-transmitting sub-electrode on the substrate is located within the orthographic projection of the second-type light-transmitting opening for the part of the light-transmitting sub-electrode to be in contact with the pixel driving circuit.

17. A manufacturing method for a display panel, comprising:
providing a substrate and forming a pixel defining layer, an isolation structure, a plurality of first shielding units, and a plurality of first electrodes on the substrate, wherein a plurality of light-transmitting openings and a plurality of isolation openings respectively corresponding to the plurality of first electrodes are formed in the isolation structure, the pixel defining layer is formed between the isolation structure and the substrate, a plurality of pixel openings in one-to-one correspondence with the plurality of isolation openings are formed in the pixel defining layer, the first shielding unit is formed between the pixel defining layer and the substrate and corresponds to at least part of the light-transmitting openings, an orthographic projection of the first shielding unit on the substrate at least partially overlaps with an orthographic projection of the corresponding light-transmitting opening on the substrate, a through hole is formed in the pixel defining layer, and the first shielding unit is connected to the isolation structure through the through hole;
sequentially depositing a light-emitting functional material layer and a conductive material layer, wherein the light-emitting functional material layer and the conductive material layer cover the isolation structure, the isolation opening, and the light-transmitting opening;
forming a first encapsulation material layer on a side, away from the substrate, of the conductive material layer;
performing patterning process on the light-emitting functional material layer, the conductive material layer, and the first encapsulation material layer to remove the light-emitting functional material layer, the conductive material layer, and the first encapsulation material layer corresponding to at least part of the light-transmitting openings and at least part of the isolation openings, wherein a light-emitting functional layer is formed by the remaining light-emitting functional material layer, a second electrode is formed by the remaining conductive material layer, an encapsulation unit is formed by the remaining first encapsulation material layer, and a light-emitting device is formed by the light-emitting functional layer, the second electrode, and the first electrode corresponding to the isolation opening where the light-emitting functional layer and the second electrode are located; and
repeating the process of preparing the light-emitting functional layer, the second electrode, and the encapsulation unit in the isolation opening where the light-emitting functional layer has not been formed, until the light-emitting device and the encapsulation unit are formed in each of the plurality of isolation openings, wherein a display functional layer is formed by the light-emitting device, and a first encapsulation layer is formed by the encapsulation unit.

18. The manufacturing method according to claim 17, wherein the first electrode comprises a light-shielding sub-electrode and a light-transmitting sub-electrode stacked in sequence, and the providing a substrate and forming a pixel defining layer, an isolation structure, a plurality of first shielding units, and a plurality of first electrodes on the substrate comprises:
depositing a light-shielding conductive material layer on the substrate and performing patterning process on the light-shielding conductive material layer to form a plurality of light-shielding sub-electrodes; and
depositing a light-transmitting conductive material layer and performing patterning process on the light-transmitting conductive material layer to form a plurality of light-transmitting sub-electrodes and the plurality of first shielding units, wherein the plurality of light-transmitting sub-electrodes are in one-to-one correspondence with the plurality of light-shielding sub-electrodes and are located on a side, facing away from the substrate, of the corresponding light-shielding sub-electrodes.

19. The manufacturing method according to claim 18, wherein the light-transmitting openings comprises a first-type light-transmitting opening and a second-type light-transmitting opening, the first shielding unit corresponds to the first-type light-transmitting opening, and the manufacturing method further comprises:
removing the conductive material layer covering the first light-transmitting opening and retaining the conductive material layer covering the second-type light-transmitting opening to form a second shielding unit during the patterning process on the conductive material layer, wherein the second shielding unit is connected to a sidewall of the isolation structure, and a shielding layer is formed by the first shielding unit and the second shielding unit.
